(19) United States
(12) Patent Application Publication
(10) Pub. No.: US 2019/0035888 A1
(43) Pub. Date: Jan. 31, 2019

(54) NANOSHEET FIELD-EFFECT TRANSISTOR WITH SELF-ALIGNED SOURCE/DRAIN ISOLATION

(71) Applicant: GLOBALFOUNDRIES Inc., Grand Cayman (KY)

(72) Inventor: Xusheng Wu, Ballston Lake, NY (US)

(21) Appl. No.: 15/658,943

(22) Filed: Jul. 25, 2017

(51) Int. Cl. H01L 29/06; H01L 21/02; H01L 21/306; H01L 29/08; H01L 29/66; H01L 29/423; H01L 29/10; H01L 29/786; H01L 29/78

(52) U.S. Cl. CPC H01L 29/0673; H01L 21/02603; H01L 21/02532; H01L 21/30604; H01L 29/0847; H01L 29/6656; H01L 29/0649; H01L 29/42392; H01L 21/02488; H01L 29/1033; H01L 29/66742; H01L 29/78651; H01L 29/785; H01L 29/66795; H01L 29/66545; H01L 21/02645

(57) ABSTRACT

Structures for a nanosheet field-effect transistor and methods for forming a structure for a nanosheet field-effect transistor. A seed layer is epitaxially grown on a substrate, and a layer stack is epitaxially grown on the seed layer. The layer stack includes a first plurality of semiconductor layers and a second plurality of semiconductor layers alternatingly arranged with the first plurality of semiconductor layers. The layer stack is patterned to form a body feature located on the seed layer. The body feature includes a plurality of nanosheet channel layers patterned from the first plurality of semiconductor layers and a plurality of sacrificial layers patterned from the second plurality of semiconductor layers. Semiconductor material for a source/drain region is epitaxially grown laterally from the nanosheet channel layers and vertically from the seed layer.

### BACKGROUND

The present invention relates to semiconductor device fabrication and integrated circuits and, more specifically, to structures for a nanosheet field-effect transistor and methods of forming a nanosheet field-effect transistor.

Device structures for a field-effect transistor generally include a body region, a source and a drain defined in the body region, and a gate electrode configured to switch carrier flow in a channel formed in the body region. When a control voltage exceeding a designated threshold voltage is applied to the gate electrode, carrier flow occurs in an inversion or depletion layer in the channel between the source and drain to produce a device output current. The body region and channel of a planar field-effect transistor are located beneath the top surface of a substrate on which the gate electrode is supported.

A fin-type field-effect transistor (FinFET) is a non-planar device structure that may be more densely packed in an integrated circuit than planar field-effect transistors. A FinFET may include a fin consisting of a solid unitary body of semiconductor material, heavily-doped source/drain regions formed in sections of the body, and a gate electrode that wraps about a channel located in the fin body between the source/drain regions. The arrangement between the gate structure and fin body improves control over the channel and reduces the leakage current when the FinFET is in its ‘Off’ state in comparison with planar transistors. This, in turn, enables the use of lower threshold voltages than in planar transistors, and results in improved performance and reduced power consumption.

Stacked nanowire or nanosheet field-effect transistors have been developed as an advanced type of FinFET that may permit additional increases in packing density. The body of a stacked nanosheet field-effect transistor includes multiple semiconductor nanosheets arranged in a three-dimensional array with a gate stack formed on the nanosheet channel regions. The gate stack may surround all sides of the channel region of each individual semiconductor nanosheet in a gate-all-around arrangement. The stacked nanosheet field-effect transistor includes source/drain regions that are epitaxially grown from the side surfaces of the semiconductor nanosheets. The substrate is etched to provide recesses in which dielectric isolation is formed prior to the growth of the source/drain regions.

The etching process, which is timed, forming the recesses for the dielectric isolation may experience over-etching that leads to recesses that are excessively deep. When the dielectric material is deposited in the recesses by a direction deposition process, an upper portion of the recesses may be unfilled. As a result, the epitaxial semiconductor material of the source/drain regions may contact the substrate over the upper portion of the recesses and the subsequently-formed source/drain regions are not fully isolated from the substrate.

The dielectric isolation lacks the ability to support the epitaxial growth of the semiconductor material of the source/drain regions. Because the epitaxial semiconductor material of the source/drain regions is epitaxially grown from the side surfaces of the semiconductor nanosheets, the seed area for epitaxial growth is inherently small, which may lead to source/drain regions with inadequate volumes.

### SUMMARY

In embodiments of the invention, a method is provided for forming a field-effect transistor. The method includes epitaxially growing a seed layer on a substrate, and epitaxially growing a layer stack on the seed layer. The layer stack includes a first plurality of semiconductor layers and a second plurality of semiconductor layers alternatingly arranged with the first plurality of semiconductor layers. The layer stack is patterned to form a body feature on the layer and to expose a portion of the seed layer adjacent to the body feature. The body feature includes a plurality of nanosheet channel layers patterned from the first plurality of semiconductor layers and a plurality of sacrificial layers patterned from the second plurality of semiconductor layers. Semiconductor material for a source/drain region is epitaxially grown laterally from a side surface of the nanosheet channel layers and vertically from the portion of the seed layer.

In embodiments of the invention, a structure is provided for a field-effect transistor. The structure includes a seed layer on a substrate, and a body feature on the layer. The body feature includes a plurality of nanosheet channel layers. The structure further includes a source/drain region with a semiconductor material that has an epitaxial relationship with the seed layer and an epitaxial relationship with the nanosheet channel layers.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-7 are cross-sectional views of a device structure at successive stages of a processing method in accordance with embodiments of the invention.

### DETAILED DESCRIPTION

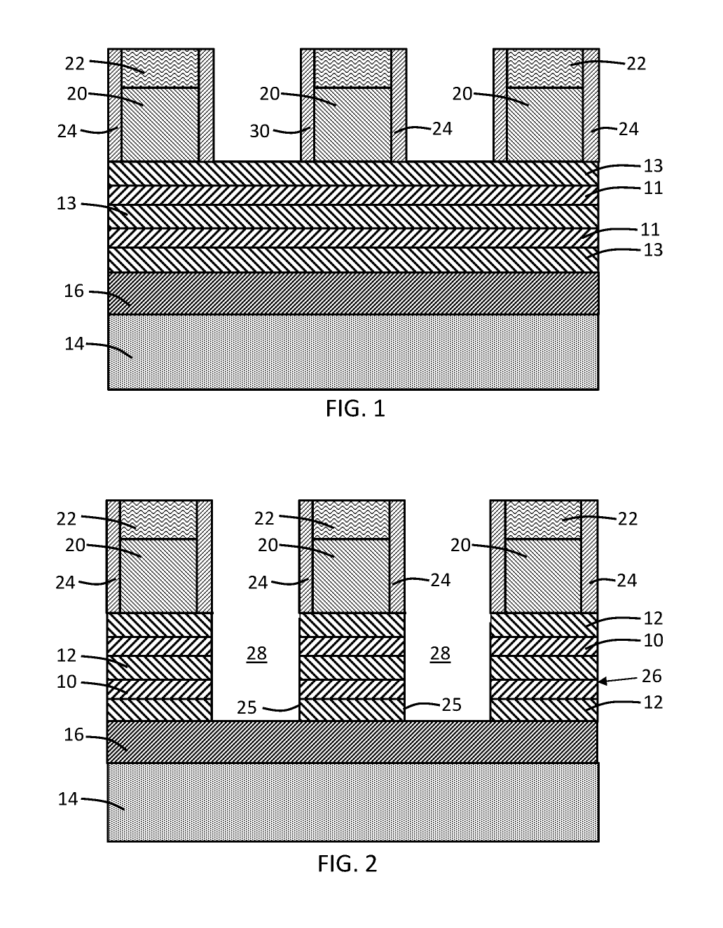

With reference to FIG. 1 and in accordance with embodiments of the invention, semiconductor layers 11 and semiconductor layers 13 are formed in an alternating series to form a layer stack on a seed layer 16. The seed layer 16 is arranged vertically between the layer stack including the semiconductor layers 11, 13 and a substrate 14. The seed layer 16 may be thicker than the semiconductor layers 11 and thicker than the semiconductor layers 13. The substrate 14 is composed of a single-crystal semiconductor material, such as single-crystal silicon.

The semiconductor layers 11, 13 may be sequentially formed by an epitaxial growth process with the composition alternated during growth through a selection of the reactants. One of the semiconductor layers 13 is epitaxially grown initially on the seed layer 16 as the bottommost layer in the layer stack. The semiconductor layers 11 are composed of a single-crystal semiconductor material, and the semiconductor layers 13 are composed of a single-crystal semiconductor material that is selected to be removed selective to the semiconductor material of the semiconductor layers 11. In an embodiment, the semiconductor layers 11 may be composed of silicon (Si), and the semiconductor layers 13 may be composed of silicon germanium (SiGe) with a germanium content of twenty percent (20%) to fifty percent (50%) that etches at a higher rate than silicon. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. The number of semiconductor layers 11 and semiconductor layers 13 may differ from the number of each depicted in the representative embodiment.

The seed layer 16 is formed by an epitaxial growth process on the substrate 14. The semiconductor layers 11, 13 have a epitaxial relationship with each other and with the seed layer 16, and the seed layer 16 has an epitaxial relationship with the semiconductor material of the substrate 14. The crystal structure of the substrate 14 provides a crystalline seed or template for the growth of the single-crystal seed layer 16 by an epitaxial process, and the crystal structure of the seed layer 16 provides a single-crystal seed or template for the growth of the single-crystal semiconductor layers 11, 13 by an epitaxial process. The seed layer 16 has a crystal structure and orientation established at least in part by the crystal structure and orientation of the substrate 14. The semiconductor layers 11, 13 have a crystal structure and orientation established at least in part by the crystal structure and orientation of the seed layer 16.

The seed layer 16 has a different composition than the semiconductor layers 11, a different composition than the semiconductor layers 13, and a different composition than the substrate 14. In embodiments, the seed layer 16 may be composed of a single-crystal rare-earth-metal oxide grown epitaxially on the substrate 14 by, for example, molecular beam epitaxy (MBE). The composition of the crystalline rare-earth-metal oxide includes a rare earth metal and oxygen. The rare earth metal may be an element from the lanthanide series of the periodic table. The composition of the crystalline rare-earth-metal oxide may include gadolinium (Gd), cerium (Ce), dysprosium (Dy), erbium (Er), europium (Eu), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), yttrium (Y), or a combination of these rare-earth metals. In an embodiment, the seed layer 16 may be composed of crystalline gadolinium oxide (Gd₂O₃).

Sacrificial gate structures 20 are formed with a given pitch on the top surface of the semiconductor layer 13 at the top of the layer stack including the semiconductor layers 11, 13. The sacrificial gate structure 20 may be composed of a polycrystalline semiconductor material, such as polycrystalline silicon (polysilicon), that is deposited by CVD and patterned with reactive ion etching (RIE). Each sacrificial gate structure 20 is covered by a dielectric cap 22 that is located on its top surface and dielectric spacers 24 adjacent to its vertical sidewalls. The dielectric spacers 24 may be composed of a low-k dielectric material, such as silicon oxycarbide (SiOC).

With reference to FIG. 2 in which like reference numerals refer to like features in FIG. 1 and at a subsequent fabrication stage of the processing method, body features 26 are formed from the semiconductor layers 11, 13 of the layer stack by an etching process that relies on the sacrificial gate structures 20 and associated dielectric spacers 24 as an etch mask. The self-aligned etching process, which may be a reactive ion etching (ME) process, relies on one or more etch chemistries to form trenches 28 that extend completely through semiconductor layers 11, 13 and that stop on the seed layer 16. The presence of the seed layer 16 ensures that the trenches 28 are etched to a uniform depth without penetrating into the substrate 14. Each of the body features 26 includes nanosheet channel layers 10 patterned from the semiconductor layers 11 and sacrificial layers 12 patterned from the semiconductor layers 13. The nanosheet channel layers 10 alternate with the sacrificial layers 12 in a vertical direction, and are aligned along respective sidewalls 25 of the body features 26. One of the sacrificial layers 12 is located adjacent to and in direct contact with the seed layer 16.

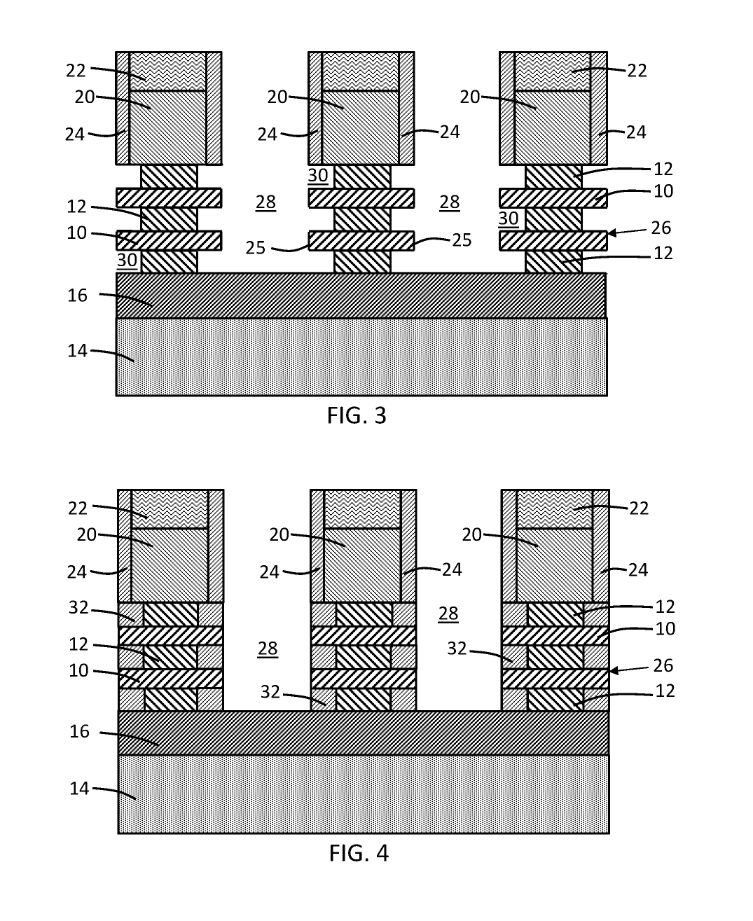

With reference to FIG. 3 in which like reference numerals refer to like features in FIG. 2 and at a subsequent fabrication stage of the processing method, the sacrificial layers 12 are laterally recessed relative to the nanosheet channel layers 10 with an isotropic etching process that etches the material constituting the sacrificial layers 12 selective to the material constituting the nanosheet channel layers 10 and the seed layer 16. The sacrificial layers 12 are only partially removed by the etching process and the sidewalls 25 of the body features 26 are indented by cavities 30.

With reference to FIG. 4 in which like reference numerals refer to like features in FIG. 3 and at a subsequent fabrication stage of the processing method, dielectric spacers 32 are formed in the cavities 30 (FIG. 3) by depositing a conformal dielectric layer that fills the cavities 30 by pinch-off and using an isotropic etching process that completely removes portions of the conformal dielectric layer that are located outside of the cavities 30. An isotropic etching process removes material in multiple directions (e.g., in lateral and vertical directions). The dielectric spacers 32 may be composed of a dielectric material, such as silicon nitride (Si₃N₄) or a low-k dielectric material, deposited by atomic layer deposition (ALD).

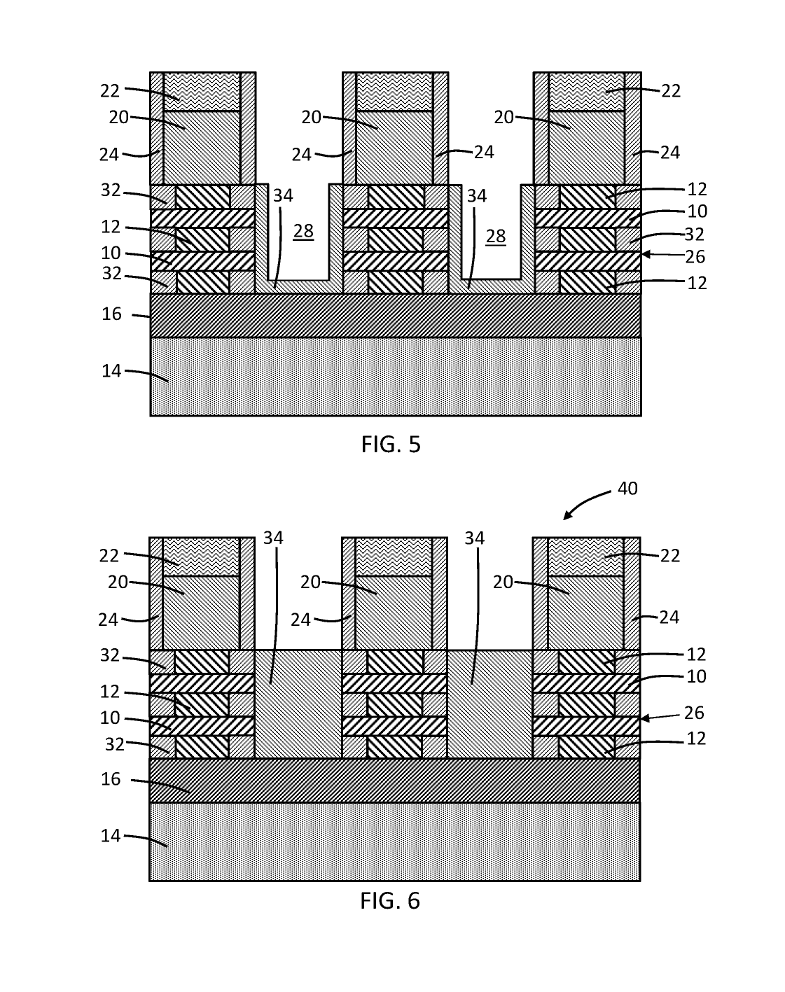

With reference to FIGS. 5 and 6 in which like reference numerals refer to like features in FIG. 4 and at a subsequent fabrication stage of the processing method, source/drain regions 34 of a field-effect transistor 40 are formed adjacent to the side surfaces of each body feature 26 that are exposed between pairs of the sacrificial gate structures 20. The source/drain regions 34 are located on and above the seed layer 16. As used herein, the term “source/drain region” means a doped region of semiconductor material that can function as either a source or a drain of a field-effect transistor. The source/drain regions 34 are connected with the nanosheet channel layers 10 and are physically isolated from the sacrificial layers 12 by the dielectric spacers 32.

The source/drain regions 34 are formed by an epitaxial growth process in which the semiconductor material grows laterally from seeds provided by the nanosheet channel layers 10 and grows vertically from a seed provided by the seed layer 16. The growth of the semiconductor material initiates from the nanosheet channel layers 10 and the seed layer 16 as depicted diagrammatically in FIG. 5, and proceeds to form the source/drain regions 34 in FIG. 6. The semiconductor material constituting the source/drain regions 34 may be heavily doped to have either p-type electrical conductivity or n-type electrical conductivity depending on the type of field-effect transistor 40. In an embodiment, the source/drain regions 34 may be formed by a selective epitaxial growth (SEG) process in which semiconductor material nucleates for epitaxial growth on single crystal surfaces (e.g., the nanosheet channel layers 10 and the seed layer 16), but does not nucleate for epitaxial growth from insulator surfaces.

The seed layer 16 supports vertical epitaxial growth of the semiconductor material of the source/drain regions 34. The source/drain regions 34 have an epitaxial relationship with the single-crystal material of the seed layer 16. The crystal structure of the seed layer 16 establishes a crystalline seed or template for the growth of the single-crystal source/drain regions 34. The source/drain regions 34 have a crystal structure and orientation established at least in part by the seed layer 16 and may have the same lattice constant or a different lattice constant. This differs from conventional constructions in which dielectric isolation, which does not support epitaxial growth, is located in the substrate 14 between the body features 26.

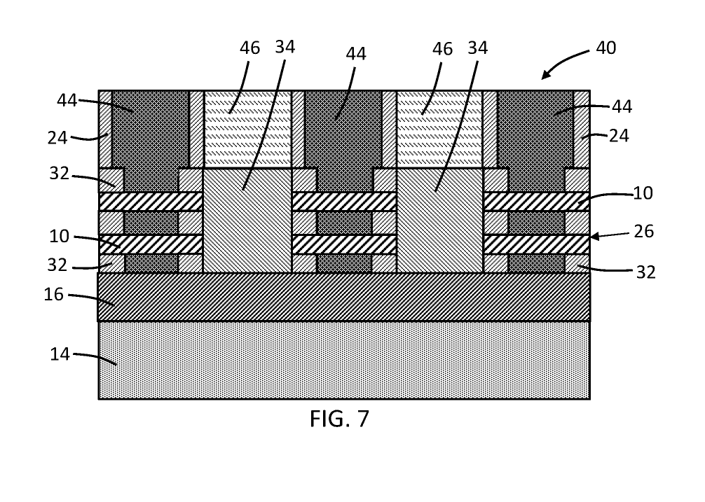

With reference to FIG. 7 in which like reference numerals refer to like features in FIG. 6 and at a subsequent fabrication stage of the processing method, a gap-fill layer 46 is deposited to fill open space of the trenches 28 arranged between the sacrificial gate structures 20 that are not already occupied by the source/drain regions 34 and then planarized. The gap-fill layer 46 may be composed of a dielectric material, such as silicon dioxide (SiO₂), deposited by CVD and may be planarized using a chemical-mechanical polishing (CMP) process. The planarization removes the dielectric caps 22 and shortens the height of the sacrificial gate structures 20 and their dielectric spacers 24.

The sacrificial layers 12 and sacrificial gate structures 20 are removed with one or more etching processes that are selective to the nanosheet channel layers 10, and are replaced with functional gate structures 44 of the field-effect transistor 40 in a replacement gate process. The dielectric spacers 32 function to mask the source/drain regions 34 from the etching process removing the sacrificial layers 12. When the sacrificial layers 12 are removed, spaces are opened that surround each of the nanosheet channel layers 10. The gap-fill layer 46 also mask the source/drain regions 34 during the replacement gate process.

The functional gate structures 44 may include a gate dielectric layer composed of a dielectric material, such as a high-k dielectric, and a metal gate electrode composed of one or more barrier metal layers and/or work function metal layers, such as titanium aluminum carbide (TiAlC) or titanium nitride (TiN), and a metal gate fill layer that is comprised of a conductor, such as tungsten (W). The gate dielectric layer is arranged between the gate electrode and the exterior surface of the nanosheet channel layers 10. The term “sacrificial gate structure” as used herein refers to a placeholder structure for a functional gate structure to be subsequently formed. The term “functional gate structure” as used herein refers to a permanent gate structure used to control output current (i.e., flow of carriers in the channel) of a semiconducting device.

The nanosheet channel layers 10 of the field-effect transistor 40 are arranged in a vertical stack. Sections of the functional gate structure 44 are located in the spaces formerly occupied by the removed sacrificial layers 12 and surround an exterior surface of the nanosheet channel layers 10 in a gate-all-around arrangement in which sections of the functional gate structure 44 are wrapped about the individual nanosheet channel layers 10. The nanosheet channel layers 10 function as channels for carrier flow that are formed during operation of the field-effect transistor 40.

The seed layer 16 extends completely and continuously beneath the body features 26 and the source/drain regions 34. The seed layer 16, which is present below the layer stack before the body features 26 are etched, provides an electrical insulator that extends beneath the source/drain regions 34 and beneath the nanosheet channel layers 10 to provide full isolation of the field-effect transistor 40 from the substrate 14. The provision of dielectric isolation using the seed layer 16 eliminates the need, as in conventional processes, to use a timed etch when forming recesses for dielectric isolation in the substrate. The dielectric isolation is provided by the layer without etching recesses in the substrate 14 and filling those recesses with dielectric material after the dielectric spacers 32 are formed as in conventional fabrication processes.

Middle-of-line (MOL) and back-end-of-line (BEOL) processing follow, which includes formation of contacts and wiring for the local interconnect structure overlying the device structure, and formation of dielectric layers, via plugs, and wiring for an interconnect structure coupled by the interconnect wiring with the functional gate structures 44 and source/drain regions 34 of the field-effect transistor 40.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for forming a field-effect transistor, the method comprising:
epitaxially growing a seed layer on a substrate;
epitaxially growing a layer stack on the seed layer, the layer stack including a first plurality of semiconductor layers and a second plurality of semiconductor layers alternatingly arranged with the first plurality of semiconductor layers;
patterning the layer stack to form a body feature on the seed layer and to expose a portion of the seed layer adjacent to the body feature, the body feature including a plurality of nanosheet channel layers patterned from the first plurality of semiconductor layers and a plurality of sacrificial layers patterned from the second plurality of semiconductor layers; and
epitaxially growing a semiconductor material for a source/drain region laterally from a side surface of the plurality of nanosheet channel layers and vertically from the seed layer.

2. The method of claim 1 wherein the seed layer is composed of a rare-earth metal oxide.

3. The method of claim 2 wherein the rare-earth metal oxide includes one or more rare-earth metal elements selected from the group consisting of gadolinium (Gd), cerium (Ce), dysprosium (Dy), erbium (Er), europium (Eu), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y).

4. The method of claim 2 wherein the rare-earth metal oxide includes an element from the lanthanide series of the periodic table.

5. The method of claim 1 wherein the seed layer is composed of gadolinium oxide.

6. The method of claim 1 wherein the first plurality of semiconductor layers are composed of silicon, the second plurality of semiconductor layers are composed of silicon-germanium, and the seed layer is composed of gadolinium oxide.

7. The method of claim 1 further comprising:
after forming the body feature, recessing the plurality of sacrificial layers relative to the plurality of nanosheet channel layers to form a plurality of cavities indented into a sidewall of the body feature; and
forming a plurality of first dielectric spacers that fill the plurality of cavities,
wherein the plurality of sacrificial layers are recessed by an etching process that etches the plurality of sacrificial layers selective to the seed layer.

8. The method of claim 1 wherein the layer stack is patterned to form the body feature with an etching process that stops vertically on the seed layer.

9. The method of claim 1 wherein the seed layer extends completely and continuously beneath the body feature and the source/drain region such that the field-effect transistor is isolated from the substrate.

10. The method of claim 1 wherein one of the plurality of sacrificial layers is in direct contact with the seed layer.

11. A field-effect transistor structure formed with a substrate, the field-effect transistor structure comprising:
a seed layer on the substrate, the seed layer composed of gadolinium oxide;
a first body feature and a second body feature on the seed layer, the first body feature and the second body feature each including a plurality of nanosheet channel layers; and
a source/drain region arranged between the first body feature and the second body feature, the source/drain region including a semiconductor material having an epitaxial relationship with the seed layer and an epitaxial relationship with the plurality of nanosheet channel layers of the first body feature and the plurality of nanosheet channel layers of the second body feature.

12. The field-effect transistor structure of claim 11 wherein the seed layer has an epitaxial relationship with the substrate.

13-16. (canceled)

17. The field-effect transistor structure of claim 11 wherein the seed layer extends completely and continuously beneath the body feature and the source/drain region.

18. The field-effect transistor structure of claim 11 further comprising:
a gate structure including a plurality of sections, each of the plurality of sections of the gate structure respectively located between pairs of the plurality of nanosheet channel layers.

19. The field-effect transistor structure of claim 18 wherein the plurality of sections of the gate structure wrap about the plurality of nanosheet channel layers.

20. The field-effect transistor structure of claim 11 wherein the seed layer is arranged vertically between the substrate and the source/drain region.
